(19) United States
(12) Patent Application Publication
(10) Pub. No.: US 2026/0040709 A1
(43) Pub. Date: Feb. 5, 2026

(54) IMAGE SENSOR

(71) Applicant: Samsung Electronics Co., Ltd., Suwon-si (KR)

(72) Inventors: Dongsik Jang, Suwon-si (KR); Euiyeol Kim, Suwon-si (KR)

(73) Assignee: Samsung Electronics Co., Ltd., Suwon-si (KR)

(21) Appl. No.: 19/267,128

(22) Filed: Jul. 11, 2025

(30) Foreign Application Priority Data
Aug. 5, 2024 (KR) 10-2024-0104241

(51) Int. Cl. H10F 39/00; H10F 39/18

(52) U.S. Cl. CPC H10F 39/807; H10F 39/182; H10F 39/811; H10F 39/813

(57) ABSTRACT

An image sensor includes: a substrate first and second surfaces; a photodiode region group including photodiode regions, each of the photodiode regions including a photodiode; a first deep isolation pattern provided within the substrate and surrounding the photodiode region group; second deep isolation patterns provided within the substrate to separate the photodiode regions from each other; connection regions that are connected to the photodiode regions and are provided between portions of the second deep isolation patterns that are spaced apart from each other, each of the connection regions including a doped isolation region; and a shared ground region provided in one of the connection regions. The photodiode regions, the doped isolation regions, and the shared ground region are doped with impurities having a first conductivity type. The photodiodes are doped with impurities having a second conductivity type, different from the first conductivity type.

### CROSS-REFERENCE TO RELATED APPLICATION

This application claims priority to Korean Patent Application No. 10-2024-0104241, filed on Aug. 5, 2024, in the Korean Intellectual Property Office, the disclosure of which is incorporated by reference herein in its entirety.

### BACKGROUND

The present disclosure relates to an image sensor.

An image sensor is a semiconductor device that converts an optical image into an electrical signal. Image sensors may be classified into charge-coupled device (CCD) and complementary metal-oxide-semiconductor (CMOS) types. A CMOS-type image sensor is abbreviated as a CMOS image sensor (CIS). The simplicity of operation and the ability to integrate a signal processing circuit onto a single chip in the CIS may facilitate a more compact product design. Each of the pixels includes a photodiode as a photoelectric conversion device, and the photodiode converts incident light into an electrical signal. The plurality of pixels are defined by a deep isolation pattern disposed therebetween.

### SUMMARY

One or more example embodiments provide an image sensor for significantly reducing the number of ground areas.

According to an aspect of an example embodiment, an image sensor includes: a substrate having a first surface and a second surface opposite the first surface; a photodiode region group including sing a plurality of photodiode regions, each of the plurality of photodiode regions including a photodiode; a first deep isolation pattern provided within the substrate and surrounding the photodiode region group; a plurality of second deep isolation patterns provided within the substrate to separate the plurality of photodiode regions from each other; a plurality of connection regions that are connected to the plurality of photodiode regions and are provided between portions of the plurality of second deep isolation patterns that are spaced apart from each other, each of the plurality of connection regions including a doped isolation region; and a shared ground region provided in one of the plurality of connection regions. The plurality of photodiode regions, the doped isolation regions, and the shared ground region are doped with impurities having a first conductivity type. The photodiodes are doped with impurities having a second conductivity type, different from the first conductivity type.

According to another aspect of an example embodiment, an image sensor includes: a substrate having a first surface and a second surface opposite the first surface; a photodiode region group including a plurality of photodiode regions, each of the plurality of photodiode regions including a photodiode; a first deep isolation pattern provided within the substrate and surrounding the photodiode region group; a plurality of second deep isolation patterns provided within the substrate to separate the plurality of photodiode regions from each other; a plurality of connection regions that are connected to the plurality of photodiode regions and are provided between the plurality of second deep isolation patterns spaced apart from each other, each of the plurality of connection regions including a doped isolation region and an additional doped isolation region; a shared ground region provided in one of the plurality of connection regions. The additional doped isolation region is adjacent to a side surface of the first deep isolation pattern or a second deep isolation pattern of the plurality of second deep isolation patterns, and extends vertically along the side surface of the first deep isolation pattern or the second deep isolation pattern. The doped isolation regions, the additional doped isolation region, and the shared ground region are doped with impurities having a same conductivity type. An impurity concentration of the shared ground region is higher than an impurity concentration of the doped isolation regions and the additional doped isolation region.

According to another aspect of an example embodiment, an image sensor includes: a substrate having a first surface and a second surface opposite the first surface; a photodiode region group including a plurality of photodiode regions arranged in a 2N×2N matrix (where N is a positive integer) in plan view, each of the plurality of photodiode regions including a photodiode; a first deep isolation pattern provided within the substrate and surrounding the photodiode region group; a plurality of second deep isolation patterns provided within the substrate to separate each of the plurality of photodiode regions from each other; a plurality of connection regions that are connected to the plurality of photodiode regions and are provided between the plurality of second deep isolation patterns spaced apart from each other, each of the plurality of connection regions including a doped isolation region and an additional doped isolation region; a shallow isolation pattern filling a shallow trench recessed from the first surface of the substrate; and a shared ground region provided in one of the plurality of connection regions. The shared ground region is provided within a connection region, among the plurality of connection regions, provided at a center of the photodiode region group, and is provided between the first surface of the substrate and the doped isolation region. A portion of the shallow isolation pattern is provided on the doped isolation region within at least one other of the plurality of connection regions. The doped isolation regions and the shared ground region are doped with impurities having a same conductivity type. An impurity concentration of the shared ground region is higher than an impurity concentration of the doped isolation regions.

### BRIEF DESCRIPTION OF DRAWINGS

The above and other aspects, features, and advantages will be more apparent from the following description of example embodiments, taken in conjunction with the accompanying drawings, in which:

FIG. 1 is a block diagram of an image sensor according to an example embodiment.

FIG. 2 is a circuit diagram of pixels of an image sensor according to an example embodiment.

FIG. 3 is a plan view illustrating an image sensor according to an example embodiment.

FIG. 4 is a cross-sectional view taken along line A-A′ of FIG. 3 according to an example embodiment.

FIG. 5 is a cross-sectional view taken along line B-B′ of FIG. 3 according to an example embodiment.

FIG. 6 is a cross-sectional view taken along line C-C′ of FIG. 3 according to an example embodiment.

FIG. 7 is a cross-sectional view taken along line D-D′ of FIG. 3 according to an example embodiment.

FIG. 8 is a cross-sectional view taken along line E-E′ of FIG. 3 according to an example embodiment.

FIG. 9 is a plan view illustrating an image sensor according to an example embodiment.

FIG. 10 is a cross-sectional view taken along line A-A′ of FIG. 9 according to an example embodiment.

FIG. 11 is a plan view illustrating an image sensor according to an example embodiment.

FIG. 12 is a cross-sectional view taken along line A-A′ of FIG. 11 according to an example embodiment.

FIG. 13A and FIG. 13B are plan views illustrating image sensors according to example embodiments, respectively.

FIG. 14 is a cross-sectional view taken along line A-A′ of FIG. 13A according to an example embodiment.

FIG. 15 is a plan view illustrating an image sensor according to an example embodiment.

FIG. 16 is a plan view illustrating an image sensor according to an example embodiment.

FIGS. 17A, 17B, 17C, 17D, 17E, 17F, 17G and 17H are cross-sectional views corresponding to line B-B′ of FIG. 3, illustrating a method of manufacturing an image sensor according to an example embodiment.

FIGS. 18A, 18B, 18C, 18D, 18E and 18F are cross-sectional views corresponding to line C-C′ of FIG. 3, illustrating a method of manufacturing an image sensor according to an example embodiment.

FIGS. 19A, 19B, 19C, 19D, 19E and 19F are cross-sectional views corresponding to line E-E′ of FIG. 3, illustrating a method of manufacturing an image sensor according to an example embodiment.

FIG. 20 is a cross-sectional view illustrating an image sensor according to an example embodiment.

FIG. 21 is a cross-sectional view illustrating an image sensor according to an example embodiment.

### DETAILED DESCRIPTION

Hereinafter, example embodiments will be described with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another embodiment also provided herein or not provided herein but consistent with the present disclosure.

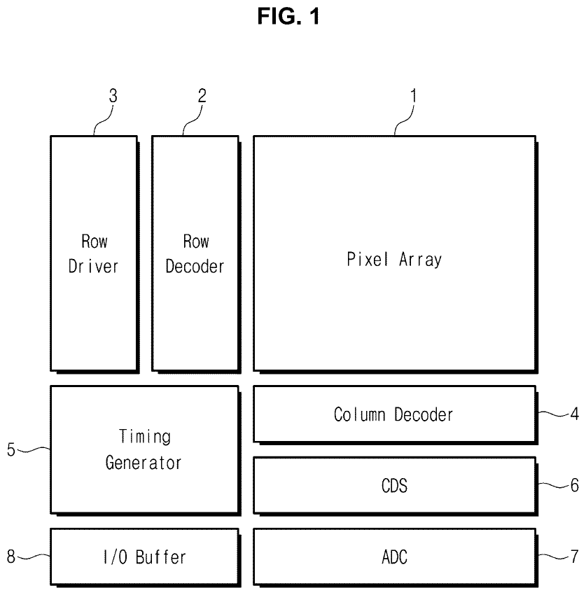

FIG. 1 is a block diagram of an image sensor according to an example embodiment.

Referring to FIG. 1, an image sensor according to an example embodiment may include a pixel array 1, a row decoder 2, a row driver 3, a column decoder 4, a timing generator 5, a correlated double sampler (CDS) 6, an analog-to-digital converter (ADC) 7, and an input/output (I/O) buffer 8.

The pixel array 1 may include a plurality of pixels arranged two-dimensionally, and the plurality of pixels may convert optical signals into electrical signals. The pixel array 1 may be driven by a plurality of driving signals (for example, a pixel select signal, a reset signal, and/or a charge transfer signal) transmitted from the row driver 3. The converted electrical signals may be provided to the correlated double sampler 6.

The row driver 3 may provide the plurality of driving signals to the pixel array 1 to drive a plurality of pixels based on a decoding result of the row decoder 2. The pixels may be arranged in a matrix, and the driving signals may be provided in units of rows.

The timing generator 5 may provide a timing signal and a control signal to the row decoder 2 and the column decoder 4.

The correlated double sampler 6 may receive electrical signals generated from the pixel array 1, and may hold and sample the received signals. The correlated double sampler 6 may perform double-sampling on a specific noise level and a signal level caused by an electrical signal to output a difference level corresponding to a difference between the noise level and the signal level.

The analog-to-digital converter 7 may convert an analog signal corresponding to the difference level, output from the correlated double sampler 6, into a digital signal and output the digital signal.

The input/output buffer 8 may latch digital signals, and may sequentially output the latched signals to an image signal processor based on a decoding result of the column decoder 4.

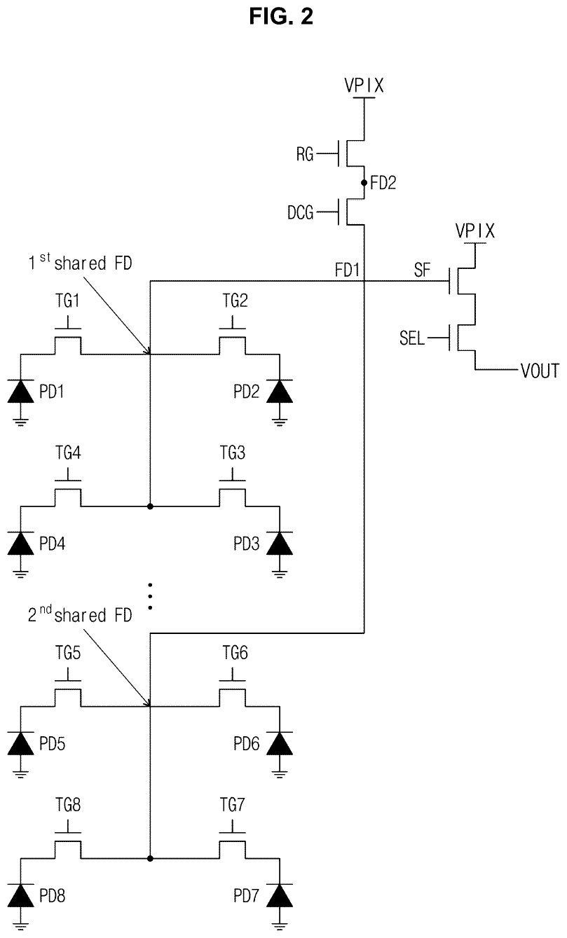

FIG. 2 is a circuit diagram for explaining a shared pixel structure of the pixel array according to an example embodiment.

Referring to FIG. 2, the pixel array may include a plurality of photodiode PDs, a plurality of transfer transistor TGs, a first floating diffusion region FD1, a second floating diffusion region FD2, a reset transistor RG, a source follower transistor SF, a selection transistor SEL, and a dual conversion gain transistor DCG. The shared pixel structure may include a plurality of photodiodes including first to eighth photodiodes PD1 to PD8. The eight photodiodes, PD1 to PD8, can be divided into two PD groups: a first PD group in which four photodiodes, PD1 to PD4, are arranged in a 2×2 matrix centered around a first shared floating diffusion region, and a second PD group in which four photodiodes, PD5 to PD8, are arranged in a 2×2 matrix centered around a second shared floating diffusion region. In this case, the first shared floating diffusion region and the second shared floating diffusion region may be connected via a connection line or a connection area and form a first floating diffusion region FD1. In some example embodiments, the eight photodiodes, PD1 to PD8, may also be configured as a single PD group arranged around the first floating diffusion region FD1. Example embodiments are not limited thereto. That is, the shared pixel structure may include a third PD group comprising four photodiodes and a fourth PD group comprising four photodiodes connected to the first floating diffusion region FD1 and the second floating diffusion region FD2.

Each pixel described in this invention may consist of one photodiode PD and one microlens, two photodiodes and one microlens, or four photodiodes and one microlens. That is, the eight photodiodes PD1 to PD8 may be included in eight, four, or two pixels. The transfer transistor TG may include first to eighth transfer transistors TG1 to TG8. However, the number of photodiodes and the number of transfer transistors are not limited thereto.

Each of the photodiode PDs are formed by forming an n-type semiconductor region on a substrate formed with a p-type semiconductor region and converts incoming light into electric charges. Each of the photodiode PDs may be coupled to a corresponding transfer transistor that transfers the generated and accumulated electric charges to the corresponding floating diffusion region. Because the floating diffusion region is a region for switching the electric charges to voltage, and has a parasitic capacitance, the electric charges may be accumulatively stored.

In some example embodiments, the first floating diffusion region FD1 may be connected to the second floating diffusion region FD2 by a dual conversion gain transistor DCG to adjust the combined capacitance. In some example embodiments, the second floating diffusion region FD2 that is a doping region and may be connected to a capacitor. The capacitor may be a metal-insulator-metal capacitor.

One end of the transfer transistor, TG1 to TG8, may be connected to the photodiode PD, PD1 to PD8, and the other end of the transfer transistor TG, TG1 to TG8, may be connected to the first or second shared floating diffusion region. The transfer transistor TG, TG1 to TG8, may be formed of a transistor driven by a predetermined bias, e.g., transfer signals. The transfer signals may be applied to a gate of the transfer transistor TG, TG1 to TG8, to transfer the electric charges generated from the photodiode PD, PD1 to PD8, to the first or second shared floating diffusion region according to the transfer signals.

The source follower transistor SF may amplify a change in electrical potential of the first floating diffusion region FD1 to which the electric charges are sent from the photodiode PD, PD1 to PD8, and output it to an output line VOUT. When the source follower transistor SF is turned on, a predetermined electrical potential provided to a drain of the source follower transistor SF, for example, a power supply voltage VPIX, may be sent to a drain region of the selection transistor SEL. In some example embodiments, a plurality of source follower transistors SFs may be connected to the first floating diffusion region FD1.

The selection transistor SEL may select a pixel to be read in units of a row. The selection transistor SEL may be made up of a transistor that is driven by a selection line that applies a predetermined bias, e.g., a row selection signal. The row selection signal may be applied through a gate of the selection transistor SEL.

The reset transistor RG may periodically reset the first floating diffusion region FD1. When the reset transistor RG is turned on by a reset signal, a predetermined electrical potential provided to the drain of the reset transistor RG, for example, the power supply voltage VPIX, may be sent to the first floating diffusion region FD1.

The dual conversion gain transistor DCG may adjust the conversion gain. For example, the conversion gain may be adjusted, by applying dual gain signal of a logic high level or applying a dual gain signal of a logic low level to a dual conversion gate of the dual conversion transistor DCG. The dual conversion gain transistor DCG may be provided between the first floating diffusion region FD1 and the second floating diffusion region FD2. The conversion gain may be adjusted, by adjusting the combined capacitance corresponding to the first and second floating diffusion regions FD1 and FD2 depending on whether the dual conversion gain transistor DCG is driven.

Although FIG. 1 shows an example in which eight photodiodes PD1 to PD8 electrically share the first floating diffusion region FD1, example embodiments are not limited thereto. That is, the number of photodiodes that electrically share the first floating diffusion region FD1 is not limited to that shown. In some example embodiments, the pixel array comprises s a non-share pixel architecture where one photodiode is connected to the first floating diffusion region FD1.

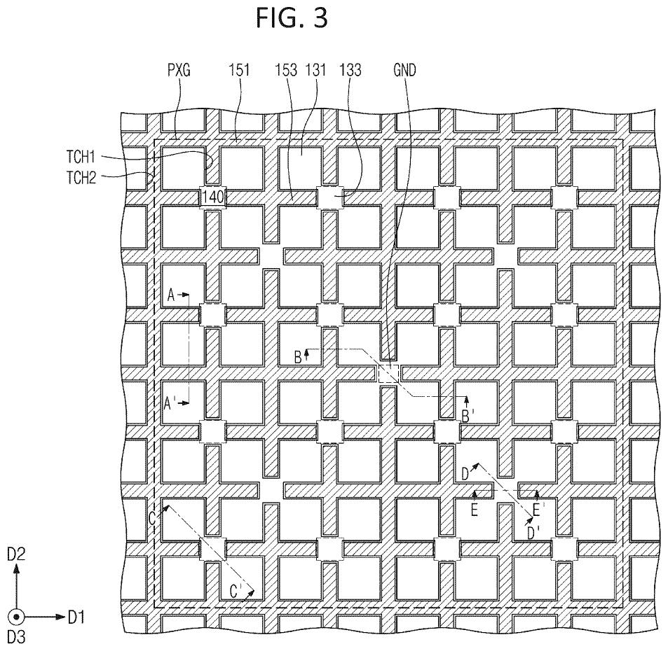

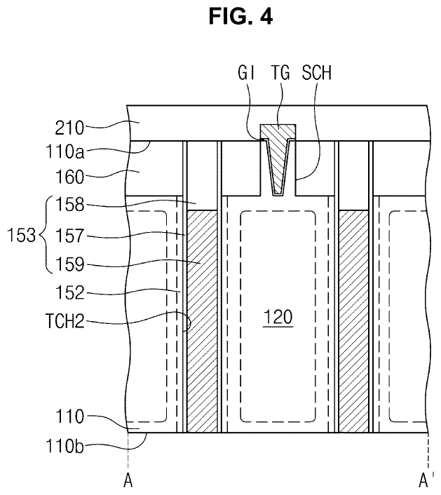

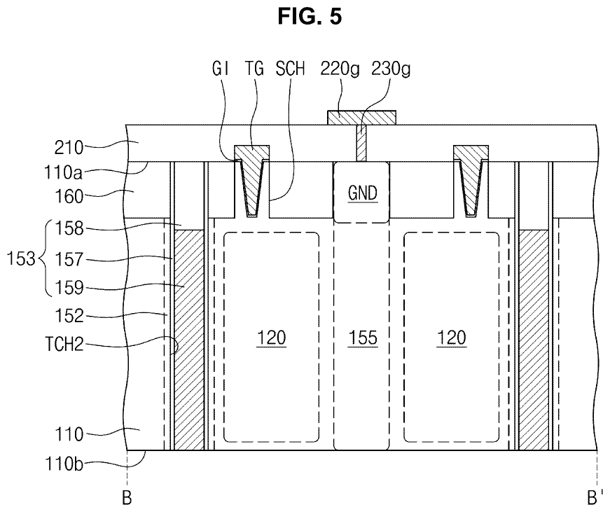

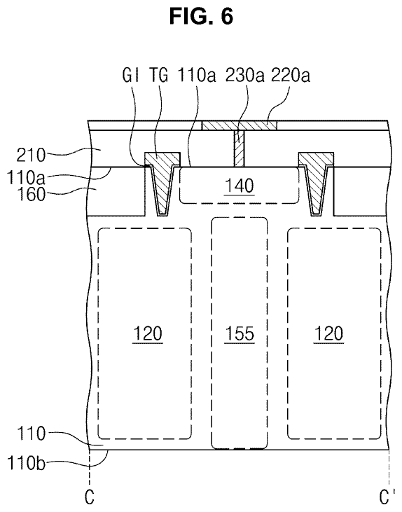

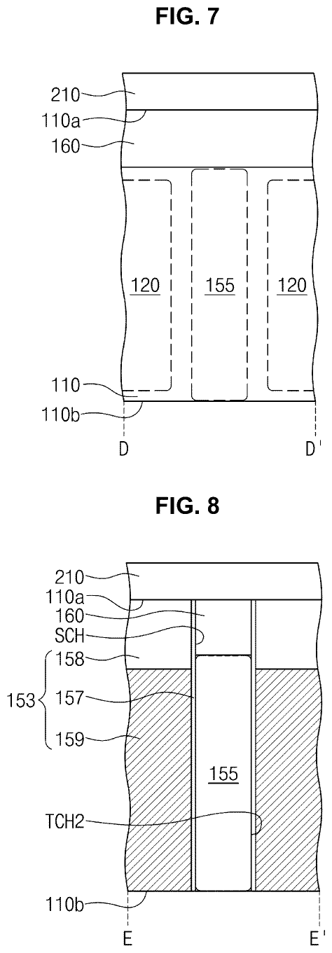

FIG. 3 is a plan view illustrating an image sensor according to an example embodiment, FIG. 4 is a cross-sectional view taken along line A-A′ of FIG. 3, FIG. 5 is a cross-sectional view taken along line B-B′ of FIG. 3, FIG. 6 is a cross-sectional view taken along line C-C′ of FIG. 3, FIG. 7 is a cross-sectional view taken along line D-D′ of FIG. 3, and FIG. 8 is a cross-sectional view taken along line E-E′ of FIG. 3.

Referring to FIGS. 3 to 8, an image sensor according to an example embodiment may include a substrate 110, a first deep isolation pattern 151, second deep isolation patterns 153, a shallow isolation pattern 160, a photodiode 120, a doped isolation region 155, an additional doped isolation region 152, a shared ground region GND, a floating diffusion region 140, and a transfer gate TG.

The substrate 110 may have a first surface 110a and a second surface 110b opposite the first surface 110a. The first surface 110a of the substrate 110 may be a front surface, and the second surface 110b of the substrate 110 may be a rear surface. Light may be incident on the second surface 110b of the substrate 110. Accordingly, the second surface 110b may be a light incident surface.

The substrate 110 may include a semiconductor substrate (for example, a silicon substrate, a germanium substrate, or a silicon-germanium substrate or a silicon-on-insulator (SOI) substrate). The substrate 110 may include dopants having a first conductivity type (hereinafter referred to as “first-type dopants”). Therefore, the substrate 110 may have the first conductivity type. The first-type dopants may be group III elements. For example, the first-type dopants may be p-type dopants such as boron (B).

A first deep isolation pattern 151 may be formed in the substrate 110 to define a pixel group PXG. The first deep isolation pattern 151 may be provided in a first deep trench TCH1 formed in the substrate 110. The first deep isolation pattern 151 may surround the pixel group PXG in plan view. The pixel group PXG may be a portion of the substrate 110 surrounded by the first deep isolation pattern 151. Although only one pixel group PXG is illustrated in FIG. 3, example embodiments are not limited thereto.

In an example embodiment, the first deep isolation pattern 151 may define a plurality of pixel groups PXG in the substrate 110, and the plurality of pixel groups PXG may be two-dimensionally arranged in a matrix.

The pixel group PXG may include a plurality of photodiode regions 131. A second deep trench TCH2 may be formed in the substrate 110 between the photodiode regions 131, and a second deep isolation pattern 153 may be provided in the second deep trench TCH2. The second deep isolation pattern 153 may separate the plurality of photodiode regions 131 from each other.

For example, in plan view, the first and second deep isolation patterns 151 and 153 may be integrally connected to each other to constitute a grid structure, and each of the photodiode regions 131 may be defined by the first and second deep isolation patterns 151, 153. According to an example embodiment, in plan view, each of the photodiode regions 131 may be a portion of the substrate 110 surrounded by the first and second deep isolation patterns 151 and 153. The photodiode regions 131 of the photodiode region group PXG may be arranged in a matrix in a first direction D1 and a second direction D2. The first and second directions D1 and D2 may be parallel to the second surface 110b of the substrate 110 and may intersect each other. For example, the first and second directions D1 and D2 may be perpendicular to each other. The first and second deep isolation patterns 151 and 153 may extend in a direction, perpendicular to the second surface 110b of the substrate 110 (for example, a third direction D3).

According to an example embodiment, the photodiode region 131 may be doped with first-type dopants. Therefore, the photodiode region 131 may have the first conductivity type. As described above, the first-type dopants may be group III elements. For example, the first-type dopants may be p-type dopants such as boron (B).

According to an example embodiment, at least some of the second deep isolation patterns 153 may be spaced apart from each other. A plurality of connection regions 133 may be provided between the second deep isolation patterns 153 spaced apart from each other. The connection regions 133 may be connected to the photodiode regions 131. For example, the photodiode region group PXG may include a plurality of photodiode regions 131 and connection regions 133. Each of the connection regions 133 may be a portion of the substrate 110.

A photodiode 120 may be provided in each of the photodiode regions 131. The photodiode 120 may be interposed between the first surface 110a and the second surface 110b of the substrate 110. In an example embodiment, the photodiode 120 may be spaced from the first surface 110a and the second surface 110b of the substrate 110. The photodiode 120 may be a doped region including dopants having a second conductivity type (hereinafter referred to as “second-type dopants”). The second conductivity type may be opposite to the first conductivity type. In an example embodiment, the second-type dopants may include group V elements. For example, the second-type dopants may include n-type dopants such as phosphorus and/or arsenic. The photodiode 120 having the second conductivity type may form a PN junction with the photodiode region 131 having the first conductivity type to constitute a photoelectric conversion device (for example, a photodiode). In an example embodiment, the photodiode 120 may refer to the photodiode PD of FIG. 2

A doped isolation region 155 may be provided in each of the connection regions 133. The doped isolation region 155 may be formed along opposite side surfaces of the spaced second deep isolation patterns 153. For example, the doped isolation region 155 may extend vertically along the opposite side surfaces of the second deep isolation patterns 133 spaced apart from each other with the connection region 133 interposed therebetween. The doped isolation region 155 may be a region of the substrate 110 doped with the first-type dopants. Accordingly, the doped isolation region 155 may electrically isolate the photodiodes 120, doped with the second-type dopants, from each other. In an example embodiment, the doped isolation region 155 may have a higher impurity concentration than the impurity concentration of the photodiode regions 131 in the substrate 110. In an example embodiment, the doped isolation region 155 may extend inwardly of the photodiode regions 131 adjacent to the connection region 133.

The additional doped isolation region 152 may be provided in each of the photodiode regions 131. The additional doped isolation region 152 may be formed along internal sidewalls of the first and second deep trenches TCH1 and TCH2. For example, the additional doped isolation region 152 may be adjacent to a side surface of the first deep isolation pattern 151 or the second deep isolation pattern 153 and may extend vertically along the side surface of the first deep isolation pattern 151 or the second deep isolation pattern 153. In an example embodiment, the additional doped isolation region 152 may be a region of the substrate 110 doped with the first-type dopants. The additional doped isolation region 152 may be connected to the doped isolation region 155. In an example embodiment, the impurity concentration of the additional doped isolation region 152 may be higher than the impurity concentration of the photodiode region 131. In an example embodiment, the impurity concentration of the additional doped isolation region 152 may be substantially the same as the impurity concentration of the photodiode region 131.

The shared ground region GND may be provided in one of the photodiode regions 131 and the connection regions 133. The shared ground region GND may be adjacent to the first surface 110a of the substrate 110. The shared ground region GND may be a region of the substrate 110 doped with the first-type dopants. In an example embodiment, the shared ground region GND may have a substantially rectangular shape in plan view, but example embodiments are not limited thereto. The shared ground region GND may have a higher impurity concentration than the impurity concentrations of the photodiode regions 131 and the doped isolation regions 155. When the image sensor operates, the shared ground region GND may receive a ground voltage. According to an example embodiment, the photodiode region group PXG may include a single shared ground region GND, and thus the photodiode regions 131 of the photodiode region group PXG may share a single shared ground region GND. For example, 64 photodiode regions 131 may constitute a single photodiode region group PXG as illustrated in FIG. 3, and the shared ground region GND may be provided in the connection region 133 provided at the center of the photodiode region group PXG. At least some of the second deep isolation patterns 153 are spaced apart from each other, so that the photodiode regions 131 provided with no ground region GND may be electrically connected to the shared ground region GND through the connection regions 133 and the doped isolation regions 155. Accordingly, a single shared ground region GND is present in a single photodiode region group PXG, so that the number of ground contact plugs 230g and interconnections 220g for supplying a ground voltage may be reduced. As a result, interconnection routing efficiency may be improved, parasitic capacitance may be reduced, and a ghost issue of the image sensor may be suppressed.

The shallow isolation pattern 160 may be provided in the substrate 110 to define active regions. The shallow isolation pattern 160 may fill a shallow trench SCH recessed inwardly of the substrate 110 from the first surface 110a. Therefore, the shallow isolation pattern 160 may be adjacent to the first surface 110a of the substrate 110. The shallow isolation pattern 160 may be exposed by the first surface 110a. The shallow isolation pattern 160 may be provided between the active regions to electrically isolate the active regions in the substrate 110 from each other. The active regions may be defined in the photodiode region 131. In plan view, the active region may be a portion of the substrate 110 surrounded by the shallow isolation pattern 160. In some example embodiments, one or more active regions may be defined in each of the photodiode regions 131.

In an example embodiment, the active regions may include a ground active region defined in one of the connection regions 133 and the shared ground region GND may be provided in the ground active region, as illustrated in FIGS. 3 and 5. For example, the connection region 133 including the shared ground region GND may not include the shallow isolation pattern 160.

A portion of the shallow isolation pattern 160 may vertically overlap the first and second deep isolation patterns 151 and 153. The shallow isolation pattern 160 may be connected to the first and second deep isolation patterns 151 and 153.

The shallow isolation pattern 160 may include at least one of various insulating materials. For example, the shallow isolation pattern 160 may include at least one of a silicon oxide, a silicon nitride, or a silicon oxynitride.

A transfer gate TG may be disposed on the first surface 110a of the substrate 110 and may be disposed on a corresponding active region of each of the photodiode regions 131. A gate dielectric GI may be disposed between the transfer gate TG and the corresponding active region. In an example embodiment, the transfer gate TG may fill a gate trench recessed inwardly of the corresponding active region from the first surface 110a. The gate dielectric GI may extend to be disposed between the transfer gate TG and an internal surface of the gate trench. The transfer gate TG may fill the gate trench, and the transfer transistor having the transfer gate may be a vertical channel transistor.

The floating diffusion region 140 may be provided in the corresponding active region on one side of the transfer gate TG. The floating diffusion region 140 may be a region doped with impurities. The floating diffusion region 140 may include second-type dopants. When light enters the photodiode 120, photoelectrons may be generated and accumulated in the photodiode 120. When the transfer transistor is turned on, the accumulated photoelectrons may be transferred from the photodiode 120 to the floating diffusion region 140 through the transfer transistor. The floating diffusion region 140 may correspond to the floating diffusion region FD of FIG. 2.

According to an example embodiment, the first and second deep isolation patterns 151 and 153 may penetrate through the substrate 110 and the shallow isolation pattern 160. Each of the first and second deep isolation patterns 151 and 153 may include an insulating liner 157, a capping insulating pattern 158, and a buried pattern 159.

The insulating liner 157 may be provided along internal surfaces of the first and second deep trenches TCH1 and TCH2. The insulating liner 157 may conformally cover the internal surfaces of the first and second deep trenches TCH1 and TCH2. The insulating liner 157 may be provided between the substrate 110 and the buried pattern 159. In addition, the insulating liner 157 may be provided between the capping insulating pattern 158 and the shallow isolation pattern 160. The capping insulating pattern 158 may be provided on the buried pattern 159.

The insulating liner 157 may include an insulating material such as a silicon-based insulating material (for example, a silicon nitride (Si₃N₄), a silicon oxide (SiO₂), a silicon oxynitride, and/or a silicon carbonitride (SiCN) and/or a high-k metal oxide (for example, a hafnium oxide (HfOx), a zirconium oxide (ZrO₂), and/or an aluminum oxide (Al₂O₃)).

In some example embodiments, although the insulating liner 157 is illustrated as a single layer, example embodiments are not limited thereto. In an example embodiment, the insulating liner 157 may include a plurality of stacked layers, and the stacked layers may include different materials.

The insulating liner 157 may have a lower refractive index than the substrate 110. Accordingly, crosstalk between the photodiode regions 131 may be eliminated or significantly reduced.

The buried pattern 159 may include an insulating material or a conductive material. For example, the buried pattern (159) may include an insulating material such as silicon oxide, aluminum oxide, tantalum oxide, and combinations thereof, or may include a conductive material such as doped polysilicon or a metal. However, the material included in the buried pattern 159 is not limited thereto, and other materials may be used.

According to an example embodiment, in the case of the buried pattern 159 includes the conductive material, the first deep isolation pattern 151 and the second deep isolation pattern 153 may be connected to each other, and the buried patterns 159 of the first and second deep isolation patterns 151 and 153 may be connected to each other. For example, the buried patterns 159 in the photodiode region group PXG may be connected to each other in plan view. Accordingly, a negative bias voltage may be simultaneously applied to all of the buried patterns 159 in the photodiode region group PXG. Thus, a white spot or dark current issue may be prevented or reduced.

The capping insulating pattern 158 may cover an upper end of the buried pattern 159 and may be adjacent to the first surface 110a of the substrate 110. The capping insulating pattern 158 may include an insulating material such as a silicon-based insulating material (for example, silicon nitride (Si₃N₄), silicon oxide (SiO₂), silicon oxynitride, and/or silicon carbonitride (SiCN) and/or a high-k metal oxide (for example, hafnium oxide (HfOx), zirconium oxide (ZrO₂), and/or aluminum oxide (Al₂O₃)).

In an example embodiment, the shallow isolation pattern 160, the insulating liner 157, and the capping insulating pattern 158 may be formed of substantially the same material. In this case, the shallow isolation pattern 160, the insulating liner 157, and the capping insulating pattern 158 may be connected without an interface. In the present disclosure, although the shallow isolation pattern 160, the insulating liner 157, and the capping insulating pattern 158 are illustrated as having boundaries between them for convenience of explanation, such illustration is exemplary only. In an actual structure, boundaries between the shallow isolation pattern 160, the insulating liner 157, and the capping insulating pattern 158 may not be visually distinguishable.

Referring to FIG. 3, the photodiode regions 131 of the photodiode region group PXG may be arranged in a matrix of 2N×2N (where N is a positive integer) in plan view. For example, N may be four, and the photodiode regions 131 may be arranged in an 8×8 matrix. In addition, a connection region 133 may be provided at the center of the photodiode region group PXG, and the shared ground region GND may be provided in the connection region 133 provided at the center of the photodiode region group PXG. In an example embodiment, the connection region 133 having the shared ground region GND may be connected to the corners of four photodiode regions 131 arranged in a 2×2 matrix, as illustrated in FIG. 3.

Referring to FIGS. 3 and 5, the shared ground region GND may be provided in the connection region 133 provided at the center of the photodiode region group PXG. The shared ground region GND may be provided between the first surface 110a of the substrate 110 and the doped isolation region 155. An interlayer dielectric 210 may be provided on the first surface 110a of the substrate 110, a ground contact plug 230g may penetrate through the interlayer dielectric 210 and be connected to the shared ground region GND, and a ground interconnection 220g may be connected to the ground contact plug 230g. The shared ground region GND may be adjacent to the doped isolation region 155. The shared ground region GND and the doped isolation region 155 may have the same conductivity type, and thus the shared ground region GND and the doped isolation region 155 may be electrically connected to each other.

In an example embodiment, some of the photodiode regions formed in the photodiode region group PXG may share the floating diffusion region 140. For example, four photodiode regions arranged in a 2×2 matrix may share the floating diffusion region 140. As illustrated in FIGS. 3 and 6, a plurality of transfer gates TG may be disposed on the active region defined by the shallow isolation pattern 160, and the floating diffusion region 140 may be provided in an active region between the plurality of transfer gates TG. The active region may be disposed in one of the connection regions 133, and the floating diffusion region 140 may be provided between the doped isolation region 155 and the first surface 110a of the substrate 110. A first contact plug 230a may penetrate through the interlayer dielectric 210 to the first surface 110a of the substrate 110, and be connected to the floating diffusion region 140. A first interconnection 220a may be provided on the first contact plug 230a. According to some example embodiments, four photodiode regions including four photodiode regions 131 may share the floating diffusion region 140 and the logic transistors RX, SX, SFX. In this regard, four photodiodes 120 and four transfer transistors TX, respectively connected to the four photodiodes 120, may share the floating diffusion region 140 and the logic transistors RX, SX, and SFX.

Returning to FIGS. 3, 7, and 8, a portion of the shallow isolation pattern 160 may fill a shallow trench SCH formed in at least one of the connection regions 133. For example, the portion of the shallow isolation pattern 160 may be provided in the connection region 133 in which the shared ground region GND is not provided. The portion of the shallow isolation pattern 160 may be provided on the doped isolation region 155.

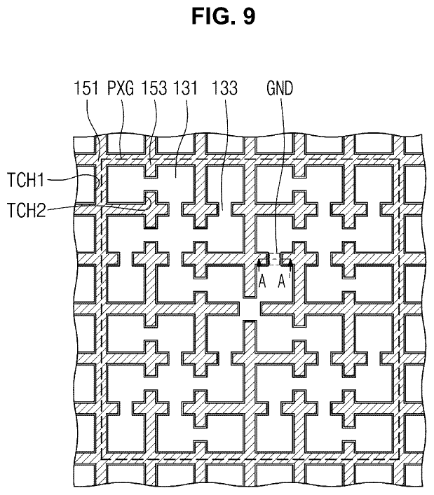

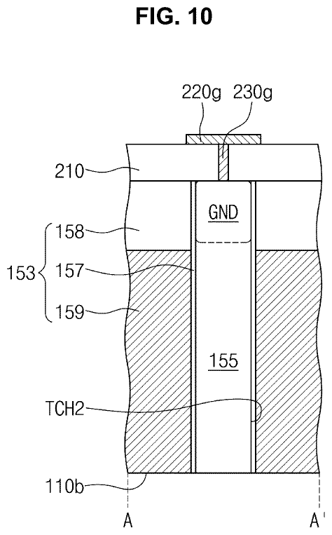

FIG. 9 is a plan view illustrating an image sensor according to an example embodiment. FIG. 10 is a cross-sectional view taken along line A-A′ of FIG. 9. Hereinafter, differences between the above-described aspects of example embodiments will be mainly described for ease of description.

Referring to FIGS. 9 and 10, a shared ground region GND and a doped isolation region 155 may be provided in a connection region 133, and a shared ground region GND may be provided between the doped isolation region 155 and a first surface 110a of a substrate 110. According to an example embodiment, the connection region 133 including the shared ground region GND may be connected to a side of the photodiode region 131, as illustrated in FIG. 9.

Other features of the image sensor of FIGS. 9 and 10 may be identical/similar to those discussed above with respect to FIGS. 3 to 8.

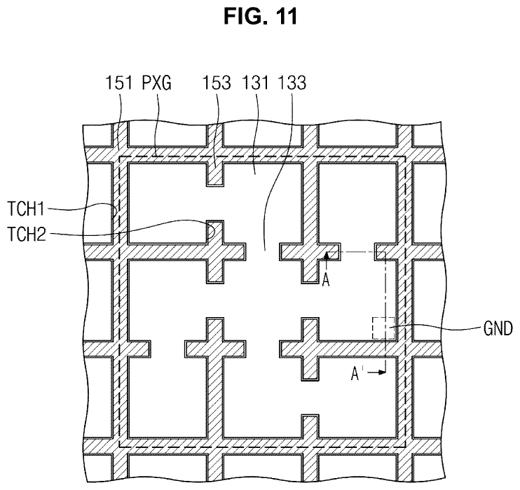

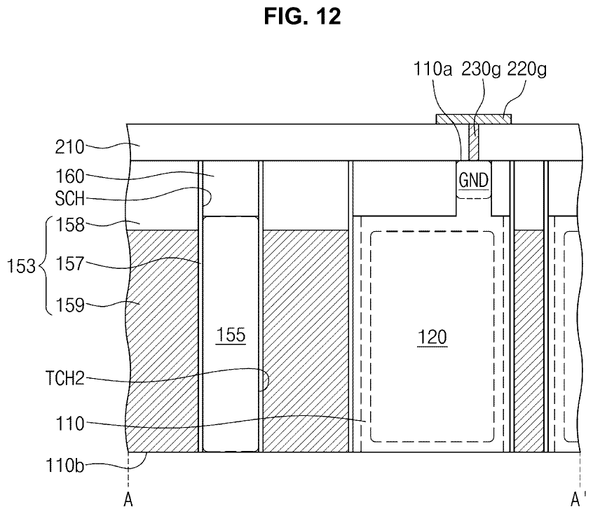

FIG. 11 is a plan view illustrating an image sensor according to an example embodiment, and FIG. 12 is a cross-sectional view taken along line A-A′ of FIG. 11. Hereinafter, differences between the above-described aspects of example embodiments will be mainly described for ease of description.

Referring to FIGS. 11 and 12, photodiode regions 131 may be arranged in a matrix of (2N+1)×(2N+1) (where N is a positive integer) in plan view. For example, N may be one and the photodiode regions 131 may be arranged in a 3×3 matrix.

In addition, a shared ground region GND may be provided in one of the photodiode regions 131. The shared ground region GND may be provided in a ground active region defined by shallow isolation patterns 160. The ground active region may be defined in one of the photodiode regions 131.

Other features of the image sensor of FIGS. 11 and 12 may be identical/similar to those discussed above with respect to FIGS. 3 to 8.

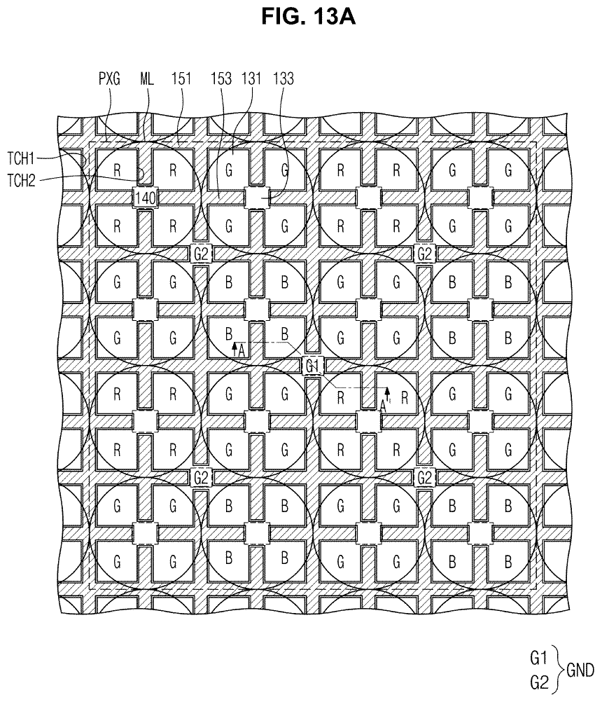

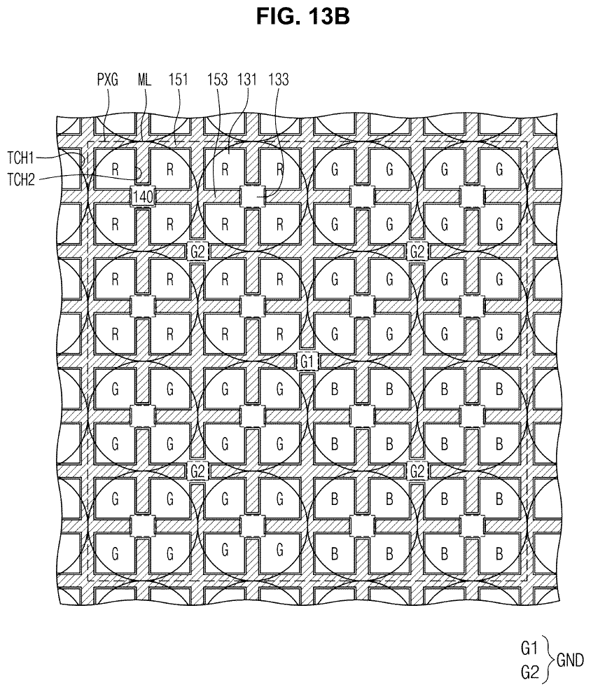

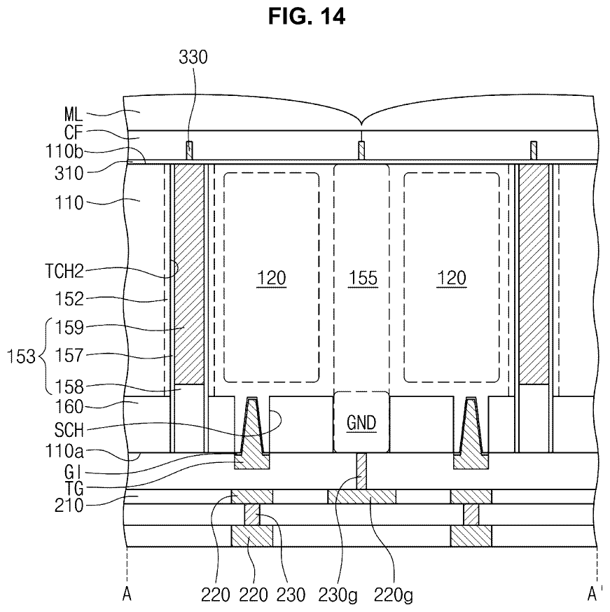

FIG. 13A and FIG. 13B is a plan view illustrating an image sensor according to an example embodiment, and FIG. 14 is a cross-sectional view taken along line A-A′ of FIG. 13A.

Referring to FIGS. 13 and 14, a photodiode region group PXG may include a plurality of sub-photodiode region groups, and each of the plurality of sub-photodiode region groups may include four photodiode regions 131 arranged in a 2×2 matrix in plan view. A connection region 133 may be provided at the center of the four photodiode regions 131.

A floating diffusion region 140 may be provided in the connection region 133 provided at the center of the four photodiode regions 131. For example, the four photodiode regions 131 may share a floating diffusion region 140 provided in the connection region 133. When light enters a photodiode 120, photoelectrons may be generated and accumulated in the photodiode 120. When a transfer transistor is turned on, the accumulated photoelectrons may be transferred from the photodiode 120 to the floating diffusion region 140 through the transfer transistor. The floating diffusion region 140 may correspond to the floating diffusion region FD of FIG. 2.

Interlayer dielectrics 210 may be disposed on a first surface 110a of a substrate 110 to cover photodiode region transistors, and interconnections 220 and contact plugs 230 may be disposed in the interlayer dielectrics 210. The interconnections 220 and the contact plugs 230 may be appropriately connected to the floating diffusion region 140 and gates and source/drain regions of the photodiode region transistors to implement photodiode regions. Each of the interlayer dielectrics 210 may be formed of an insulating material (for example, a silicon oxide, a silicon nitride, and/or a silicon oxynitride), and the interconnections 220 and the contact plugs 230 may be formed of a conductive material (for example, metal, metal nitride, and/or metal silicide).

An upper insulating layer 310 may be provided on a second surface 110b of the substrate 110. The upper insulating layer 310 may cover the second surface 110b of the substrate 110 and upper surfaces of the first and second deep isolation patterns 151 and 153. The upper insulating layer 310 may be formed of a transparent insulating material. The upper insulating layer 310 may have a single-layer structure or a multilayer structure.

In an example embodiment, the upper insulating layer 310 may function as an antireflective layer and/or a fixed charge layer. In an example embodiment, the upper insulating layer 310 may be used as the antireflective layer, and the upper insulating layer 310 may include, for example, at least one of a hafnium oxide (HfOx), a zirconium oxide (ZrO₂), or an aluminum oxide (Al₂O₃). The upper insulating layer 310 may prevent the reflection of light such that light incident on the second surface 110b of the substrate 110 may smoothly reach the photodiode 120. In an example embodiment, the upper insulating layer 310 may be used as the fixed charge layer, and the upper insulating layer 310 may have negative fixed charges. The upper insulating layer 310 may include a metal oxide or a metal fluoride including at least one of hafnium, zirconium, tantalum, yttrium, or lanthanoid. In an example embodiment, the upper insulating layer 310 may include the fixed charge layer and the antireflective layer stacked sequentially. In an example embodiment, the upper insulating layer 310 may include or further include at least one of a silicon oxide, a silicon nitride, and a silicon oxynitride.

A grating pattern 330 may be provided on the second surface 110b of the substrate 110 with the upper insulating layer 310 interposed therebetween. The grating pattern 330 may define openings, respectively corresponding to the photodiode regions 131. A color filter array, including two-dimensionally arranged color filters CF, may be provided on the second surface 110b of the substrate 110. The color filter array may be provided on the upper insulating layer 310, and each of the color filters CF may fill corresponding opening(s) among the openings of the grating pattern 330. A lens array, including two-dimensionally arranged microlenses ML, may be provided on the second surface 110b of the substrate 110 with the color filter array interposed therebetween. For example, the color filter array CFA may be disposed between the lens array MLA and the upper insulating layer 310.

The grating pattern 330 may guide incident light into the photodiode 120. The grating pattern 330 may have a single-layer structure or a multilayer structure. The grating pattern 330 may include a metal-containing material (for example, a metal (for example, titanium) and/or a metal nitride (for example, titanium nitride) and/or a low refractive index material. The low refractive index material may include a polymer and silica nanoparticles in the polymer. The low refractive index material may have insulating properties.

In an example embodiment, the grating pattern 330 may vertically overlap the first and second deep isolation patterns 151 and 153. However, example embodiments are not limited thereto. In an example embodiment, the grating pattern 330 may have a structure, horizontally offset from the first and second deep isolation patterns 151 and 153. The offset structure may be intentionally selected to optimize a light path in consideration of a manufacturing process margin and/or an angle at which incident light travels.

In an example embodiment, each of the color filters CF may cover corresponding photodiode region groups PXG. For example, each of the color filters CF may be disposed on four photodiode regions 131 arranged in a 2×2 matrix in plan view. For example, each of the color filters CF may cover each of adjacent photodiode region groups PXG. However, example embodiments are not limited thereto.

Each of the color filters CF may vertically overlap corresponding sub-photodiode region groups. Each of the color filters CF may cover four photodiode regions 131 of a corresponding sub-photodiode region group. However, example embodiments are not limited thereto. In an example embodiment, each of the color filters CF may have a structure, horizontally offset from a corresponding photodiode region group PXG. The offset structure may be intentionally selected to optimize a light path in consideration of a manufacturing process margin and/or an angle at which incident light travels.

Each of the color filters CF may have one color, among red, green, and blue colors. Namely, the color filters CF may have a red color filter R, a green color filter G, and a blue color filter B and the sub-photodiode region may correspond to one of the red, green, and blue color filters R, G, and B. In one example embodiment, referring to FIG. 13A, four photodiode regions 131 arranged in a 2×2 matrix may constitute one sub-photodiode region. Four sub-photodiode regions may be arranged in a 2×2 matrix to constitute a Bayer pattern. In the Bayer pattern, the red color filter R and the blue color filter B may be arranged in one diagonal direction in the sub-photodiode regions, and two green color filters G may be arranged in the other diagonal direction. The number of photodiode regions constituting one sub-photodiode region is not limited thereto, and for example, 16 photodiode regions 131 arranged in a 4×4 matrix as illustrated in FIG. 13b may constitute one sub-photodiode region. Alternatively, each of the color filters CF may have one color, among cyan, magenta, and yellow colors.

The microlenses ML may cover the sub-photodiode region groups, respectively. For example, each of the microlenses ML may cover the four photodiode regions 131 of each of the sub-photodiode region groups. In an example embodiment, one microlens ML may be provided on each photodiode region 131. Alternatively, each of the microlenses ML may cover a different number of photodiode regions 131, for example, eight, sixteen, or the like photodiode regions 131. Each of the microlenses ML may be provided to collect incident light and may include a spherical lens, an aspherical lens, or a combination thereof. For example, each of the microlenses ML may have a convex shape in cross-sectional view.

The microlenses ML are transparent, which allows light to pass therethrough. The microlenses ML may be formed of an organic material such as a polymer. For example, the microlenses ML may include a photoresist material or a thermosetting resin.

In one embodiment, the photodiode region group PXG may include, but is not limited to, a single shared ground region GND. In an example embodiment, the shared ground region GND may be provided in plural. The shared ground region GND may include a first shared ground region G1 and/or a second shared ground region G2. The first shared ground region G1 may be provided in the connection region 133 provided at the center of the photodiode region group PXG and the second shared ground region G2 may be provided within the connection region 133 excluding the center of the photodiode region group PXG. The second shared ground G2 region may be provided in a single or plural numbers. For example, referring to FIGS. 13A and 13B, the first shared ground region G1 may be provided at a position corresponding to the center of the photodiode region group PXG, and the second shared ground region G2 may be arranged at the center of four sub-photodiode regions constituting one Bayer pattern, or at the center of each sub-photodiode region. The second shared ground region G2 may be omitted according to an embodiment.

Other features of the image sensor of FIGS. 13A, 13B, and 14 may be identical/similar to those discussed above with respect to FIGS. 3 to 8.

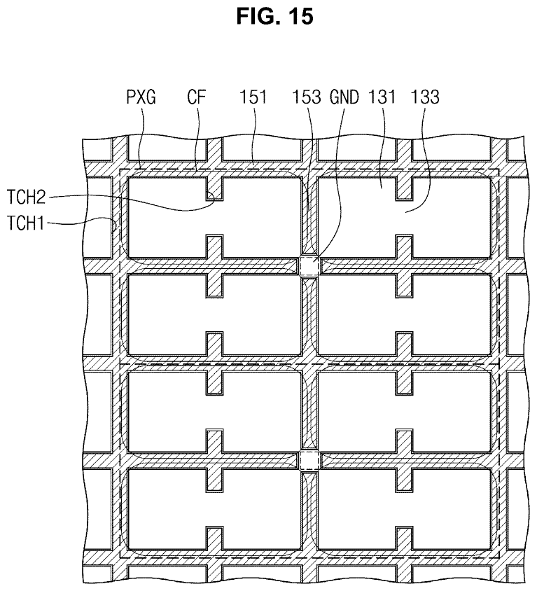

FIG. 15 is a plan view illustrating an image sensor according to an example embodiment.

Referring to FIG. 15, two photodiode regions 131 may constitute a sub-photodiode region group, and four sub-photodiode region groups may constitute a photodiode region group PXG.

For example, the photodiode region group PXG may include eight photodiode regions 131 arranged in a 2×4 matrix in plan view.

In an example embodiment, a connection region 133 may be provided at the center of the photodiode region group PXG and at the center of each of the sub-photodiode region groups. For example, the connection region 133 may be provided at the center of the four sub-photodiode region groups and at the center of the two photodiode regions 131 constituting each sub-photodiode region group.

In an example embodiment, a shared ground region GND may be provided in the connection region 133 provided at the center of the four sub-photodiode region groups.

A floating diffusion region 140 (see FIG. 13A and FIG. 13B) may be provided in the sub-photodiode region group. For example, the two photodiode regions 131 may share the floating diffusion region 140. When light enters a photodiode 120 (see FIG. 13A and FIG. 13B), photoelectrons may be generated and accumulated in the photodiode 120. When the transfer transistor is turned on, the accumulated photoelectrons may be transferred from the photodiode 120 to the floating diffusion region 140 through a transfer transistor.

In an example embodiment, each of the color filters CF may cover the corresponding sub-photodiode region groups. For example, each of the color filters CF may be disposed on two photodiode regions 131 arranged in a 1×2 matrix in plan view. For example, each of the color filters CF may cover each of adjacent sub-photodiode region groups. The arrangement of the microlenses ML provided on the color filters CF may be substantially the same as the arrangement of the color filters CF.

Other features of the image sensor of FIG. 15 may be identical/similar to those discussed above with respect to FIGS. 3 to 8.

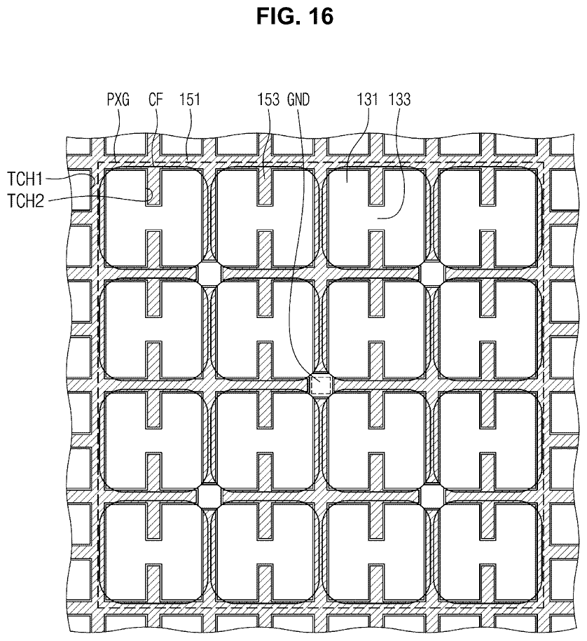

FIG. 16 is a plan view illustrating an image sensor according to an example embodiment.

Referring to FIG. 16, two photodiode regions 131 may constitute a sub-photodiode region group, and 16 sub-photodiode region groups may constitute a photodiode region group PXG. For example, the photodiode region group PXG may include 32 photodiode regions 131 arranged in a 4×8 matrix in plan view.

In an example embodiment, a connection region 133 may be provided at the center of the photodiode region group PXG and at the center of each of the sub-photodiode region groups. For example, the connection region 133 may be provided at the center of the 16 sub-photodiode region groups and at the center of the two photodiode regions 131 constituting each sub-photodiode region group.

In an example embodiment, a shared ground region GND may be provided in the connection region 133 provided at the center of the 16 sub-photodiode region groups.

In an example embodiment, a floating diffusion region 140 (see FIG. 13A and FIG. 13B) may be provided in each of the photodiode regions 131. Also, the photodiode 120 (see FIG. 13A and FIG. 13B) may be provided in each of the photodiode regions 131. For example, two floating diffusion regions 140 and two photodiodes 120 may be provided in each of the sub-photodiode region groups.

In an example embodiment, each of the color filters CF may cover the corresponding sub-photodiode region groups. For example, each of the color filters CF may be disposed on each of the sub-photodiode region groups including two photodiode regions 131 in plan view. For example, each of the color filters CF may cover a pair of adjacent photodiode regions 131. The arrangement of the microlenses ML provided on the color filters CF may be substantially the same as the arrangement of the color filters CF.

In an example embodiment, each of the microlenses ML may cover two photodiode regions 131, so that light may enter the photodiode 120 provided in each of the two photodiode regions 131. The two photodiode regions 131 may perform an autofocusing function, other than a photoelectric conversion function for converting light signals into electrical signals. For example, the two photodiode regions 131 may detect a phase difference of light incident through the corresponding microlens ML, and the autofocusing function may be performed based on data of the detected phase difference. For example, the data of the detected phase difference may be transmitted to an autofocusing circuit, and the autofocusing circuit may adjust an objective lens based on the transmitted data of the phase difference.

Other features of the image sensor of FIG. 16 may be identical/similar to those discussed above with respect to FIGS. 3 to 8.

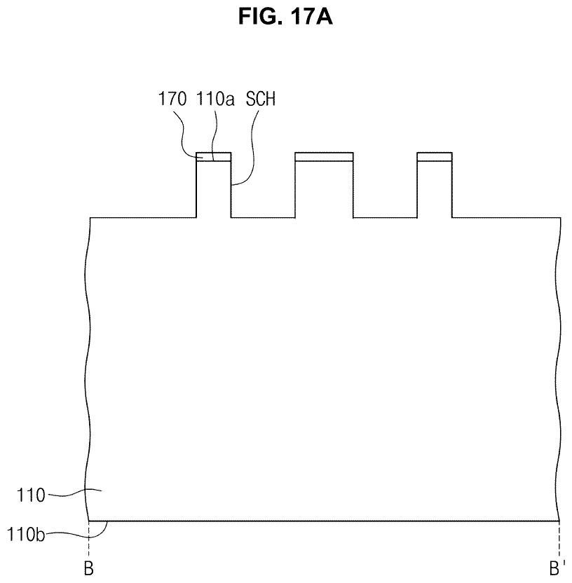

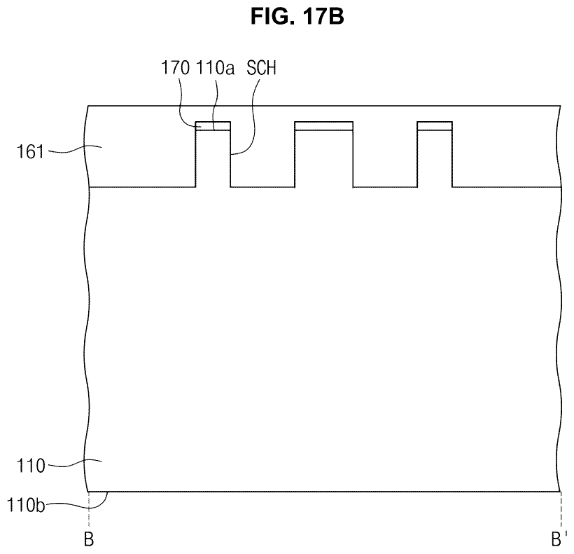

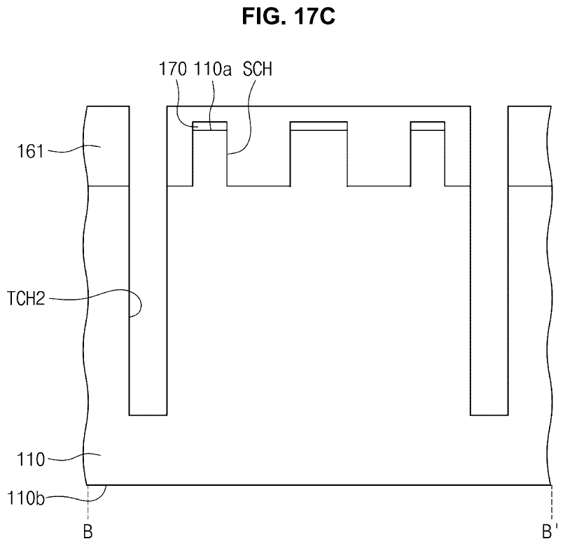

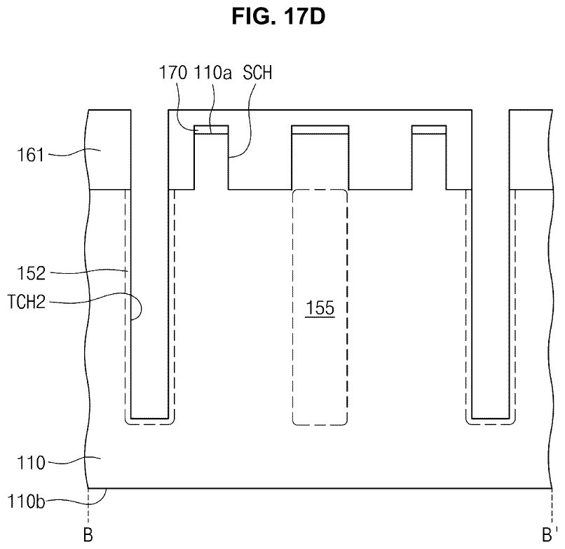

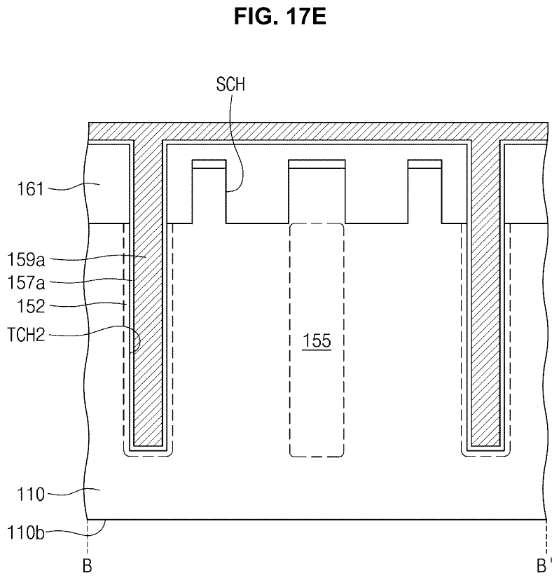

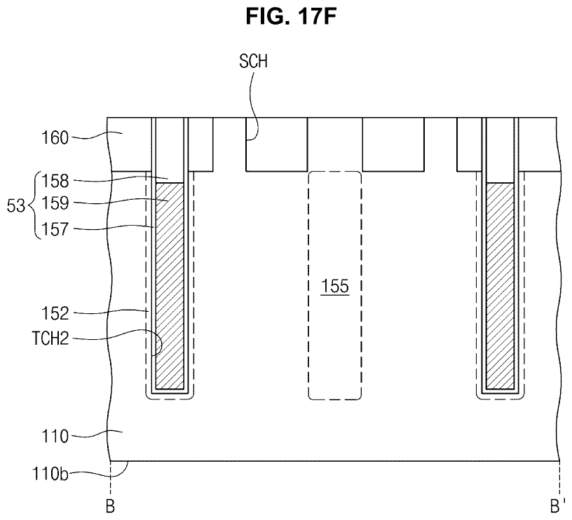

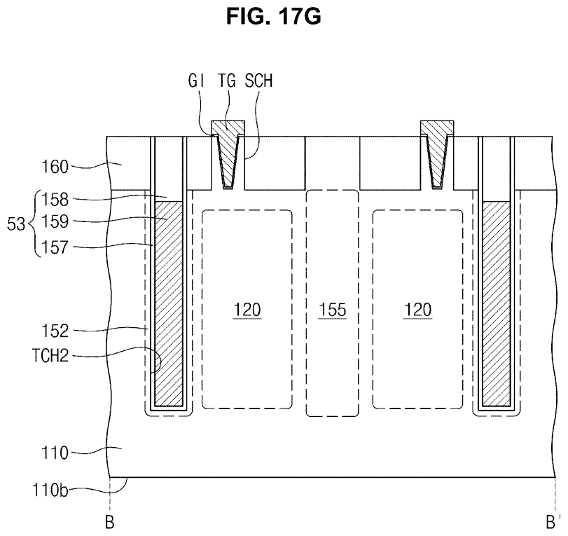

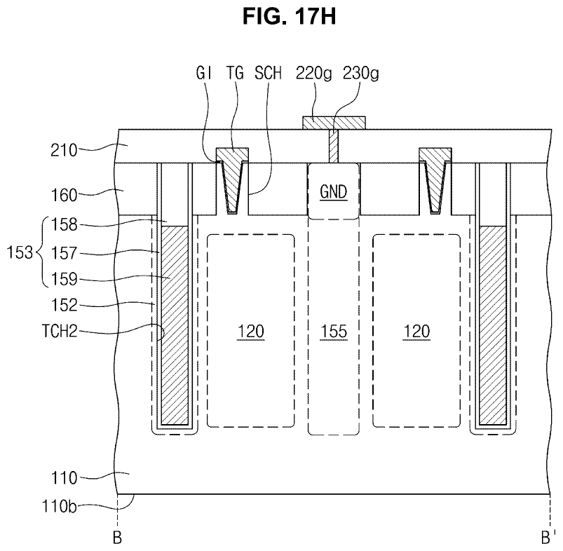

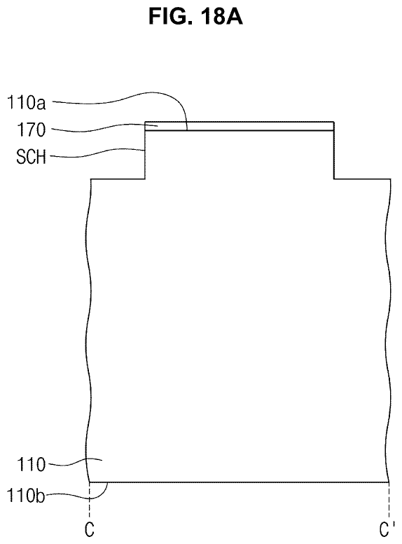

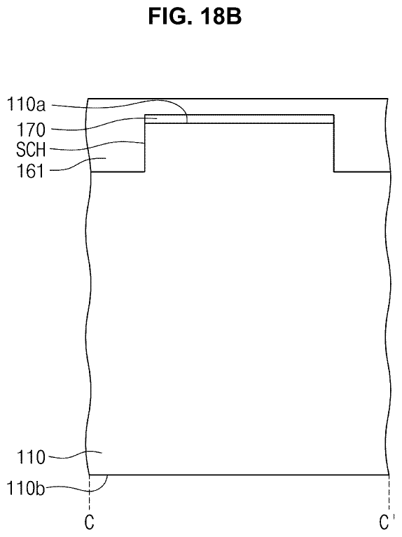

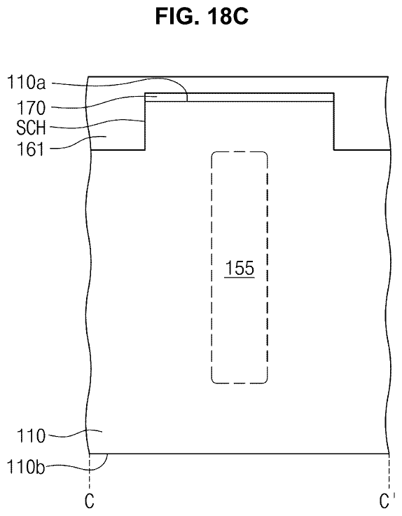

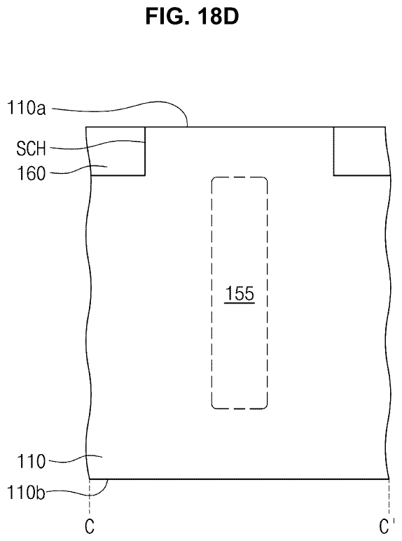

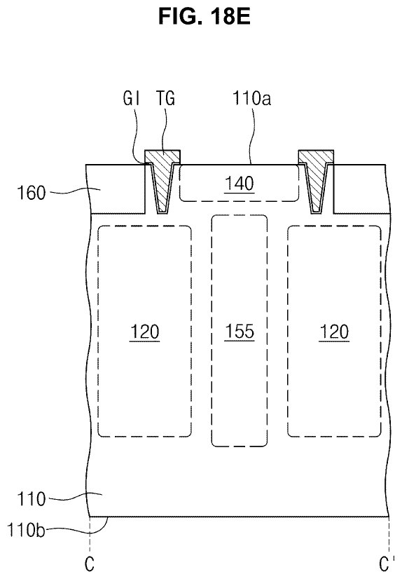

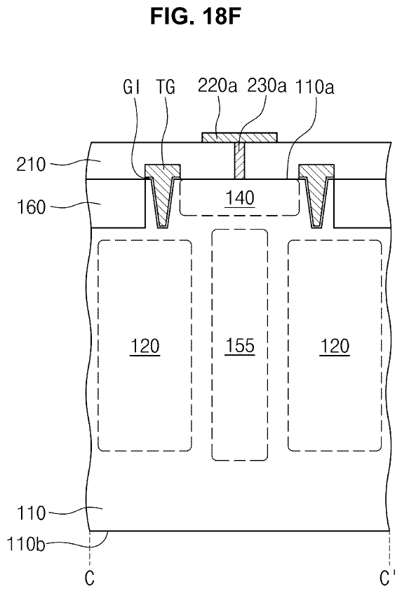

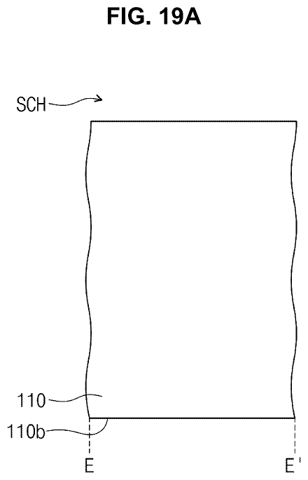

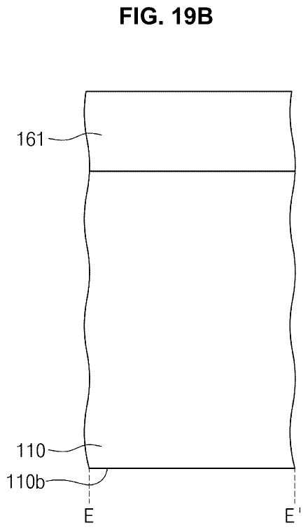

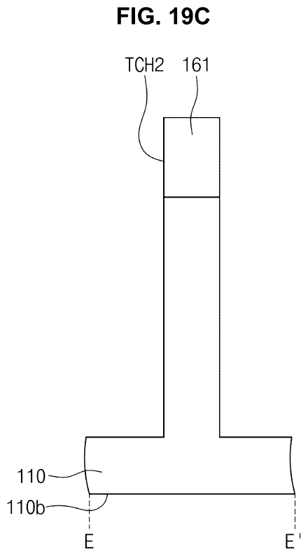

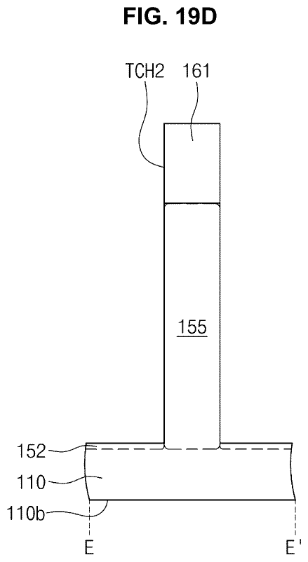

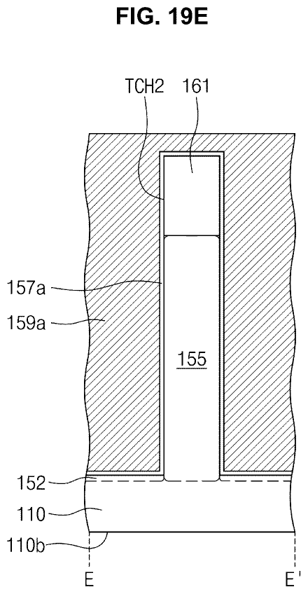

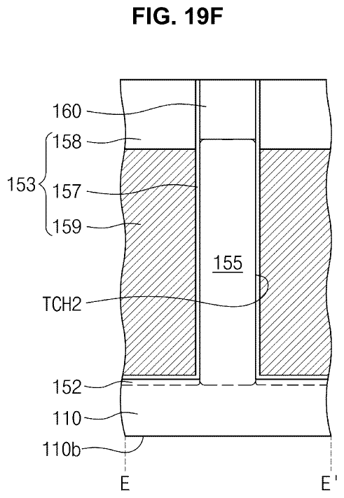

FIGS. 17A to 17H are cross-sectional views corresponding to line B-B′ of FIG. 3, illustrating a method of manufacturing an image sensor according to an example embodiment. FIGS. 18A to 18F are cross-sectional views corresponding to line C-C′ of FIG. 3, illustrating a method of manufacturing an image sensor according to an example embodiment. FIGS. 19A to 19F are cross-sectional views corresponding to line E-E′ of FIG. 3, illustrating a method of manufacturing an image sensor according to an example embodiment.

Referring to FIGS. 17A, 18A, and 19A, a hard mask pattern 170 may be formed on the first surface 110a of the substrate 110 to define a shallow trench SCH. The hard mask pattern 170 may be formed of a material having etching selectivity with respect to the substrate 110. For example, the hard mask pattern 170 may be formed of at least one of a silicon oxide, a silicon nitride, or a silicon oxynitride. The substrate 110 may be doped with first-type dopants.

The substrate 110 may be etched using the hard mask pattern 170 as an etch mask to form a shallow trench SCH.

Referring to FIGS. 17B, 18B, and 19B, a first insulating layer 161 may be formed on the first surface 110a of the substrate 110 to fill the shallow trench SCH. The first insulating layer 161 may cover the hard mask pattern 170. The first insulating layer 161 may include an insulating material. The first insulating layer 161 may be formed using at least one of a deposition process or an oxidation process.

Referring to FIGS. 17C and 19C, the first insulating layer 161 and the substrate 110 may be patterned to form a first deep trench TCH1 (see FIG. 3) and second deep trenches TCH2. The first and second deep trenches TCH1 and TCH2 may extend from the first surface 110a of the substrate 110 toward the second surface 110b of the substrate 110. The first and second deep trenches TCH1 and TCH2 may penetrate through portions of the first insulating layer 161 in the shallow trench SCH. The first deep trench TCH1 may define a photodiode region group PXG, and the first and second deep trenches TCH1 and TCH2 may define photodiode regions 131 and connection regions 133.

Referring to FIGS. 17D, 18C, and 19D, a doping process may be performed through internal surfaces (for example, internal side surface and bottom surfaces) of the first and second deep trenches TCH1 and TCH2. The doping process may be a process of injecting first-type impurities into the substrate 110 through the internal surfaces of the first and second deep trenches TCH1 and TCH2. In an example embodiment, the doping process may use plasma. For example, in the doping process, a gas containing impurities may be ionized to generate plasma, and ions and/or radicals in the plasma may be injected into the substrate 110 through the internal surfaces of the first and second deep trenches TCH1 and TCH2. Thus, a doped isolation region 155 may be formed in the connection region 133 between the second deep trenches TCH2 that are adjacent to each other but separated from each other, and an additional doped isolation region 152 may be formed in the photodiode regions 131 adjacent to the internal side surfaces of the first and second deep trenches TCH1 and TCH2.

As described above, the doped isolation region 155, the additional doped isolation region 152, and the photodiode regions 131 may have the same conductivity type, and impurity concentrations of the doped isolation region 155 and the additional doped isolation region 152 may be higher than an impurity concentration of the photodiode regions 131.

Referring to FIGS. 17E and 19E, an insulating liner 157a may be conformally formed on the first surface 110a of the substrate 110 having the first and second deep trenches TCH1 and TCH2, and a buried layer 159a may be formed on the insulating liner 157a to fill the first and second deep trenches TCH1 and TCH2. The insulating liner 157a may be formed using at least one of a deposition process or an oxidation process, and the buried layer 159a may be formed using a deposition process.

Referring to FIGS. 17F, 18D, and 19F, the buried layer 159a may be etched to form a buried pattern 159 in the first and second deep trenches TCH1 and TCH2. An upper end of the buried pattern 159 may be lower than the first surface 110a of the substrate 110.

A second insulating layer may be formed on the substrate 110 having the buried pattern 159. The second insulating layer may cover the insulating liner 157a, the first insulating layer 161, and the buried pattern 159. The second insulating layer may fill upper regions of the first and second deep trenches TCH1 and TCH2. The second insulating layer may include an insulating material. The second insulating layer may be formed by a deposition process.

A planarization process may be performed on the second insulating layer until the first surface 110a of the substrate 110 is exposed. The hard mask pattern 170, the first insulating layer 161, the insulating liner 157a, and the second insulating layer on the first surface 110a may be removed by the planarization process. The planarization process may be performed using at least one of an etch-back process or a chemical mechanical polishing (CMP) process.

An insulating liner 157, a capping insulating pattern 158, and a shallow isolation pattern 160 may be formed by the planarization process and may be exposed on the first surface 110a of the substrate 110.

The shallow isolation pattern 160 may be provided in the shallow trench SCH to define active regions in the photodiode regions 131. Each of the active regions may be a portion of the substrate 110, surrounded by the shallow isolation pattern 160, in plan view.

The capping insulating pattern 158, the insulating liner 157, and the buried pattern 159 may constitute the first and second deep isolation patterns 151 and 153.

Referring to FIGS. 17G and 18E, second-type impurities may be implanted into the substrate 110 to form a photodiode 120 in each of the photodiode regions 131. In an example embodiment, the photodiodes 120 may be formed before the shallow trench SCH is formed or before the first and second deep isolation patterns 151 and 153 are formed.

A gate trench may be formed in a corresponding active region of each of the photodiode regions 131. A gate dielectric layer GI may be formed on internal surfaces of the gate trenches and on the active regions, and a gate conductive layer may be formed on the gate dielectric layer GI. The gate conductive layer may fill the gate trenches. The gate conductor may be patterned to form transfer gates TG. Gates of logic transistors may also be formed on corresponding active regions of the photodiode regions 131, respectively.

Returning to FIG. 18E, second-type impurities may be implanted into the active regions, defined by the shallow isolation pattern 160, to form a floating diffusion region 140. The floating diffusion region 140 may be formed between the doped isolation region 155 and the first surface 110a of the substrate 110, and may be provided between the transfer gates TG.

Referring to FIGS. 17H and 18F, a shared ground region GND may be formed in a corresponding connection region among the connection regions 133. In an example embodiment, the shared ground region GND may be formed in a ground active region defined in the corresponding connection region 133. The shared ground region GND may be doped with first-type impurities to be formed. The shared ground region GND may be formed using a doping process or an ion implantation process.

An interlayer dielectric 210 may be formed on the first surface 110a of the substrate 110. A ground contact plug 230g may be formed on the first surface 110a of the substrate 110. The ground contact plug 230g may be connected to the shared ground region GND. For example, the ground contact plug 230g may be formed on the shared ground region GND through the interlayer dielectric 210.

A first contact plug 230a may be formed on the first surface 110a of the substrate 110.

The first contact plug 230a may be connected to the floating diffusion region 140. The first contact plug 230a may be connected to the floating diffusion region 140 through the interlayer dielectric 210 to implement the pixel PXL of FIG. 2.

A ground interconnection 220g may be formed on the interlayer dielectric 210 and connected to the ground contact plug 230g, and a first interconnection 220a may be formed on the interlayer dielectric 210 and connected to the first contact plug 230a. Subsequent processes may be performed on the first surface 110a of the substrate 110.

After the completion of the subsequent processes on the first surface 110a, the second surface 110b of the substrate 110 may be polished until the buried pattern 159 is exposed. The second surface 110b of the substrate 110 may be polished by a chemical mechanical polishing (CMP) process. A hydrogen/deuterium annealing process may be performed to cure defects (for example, dangling bond, or the like) on the polished second surface 110b of the substrate 110.

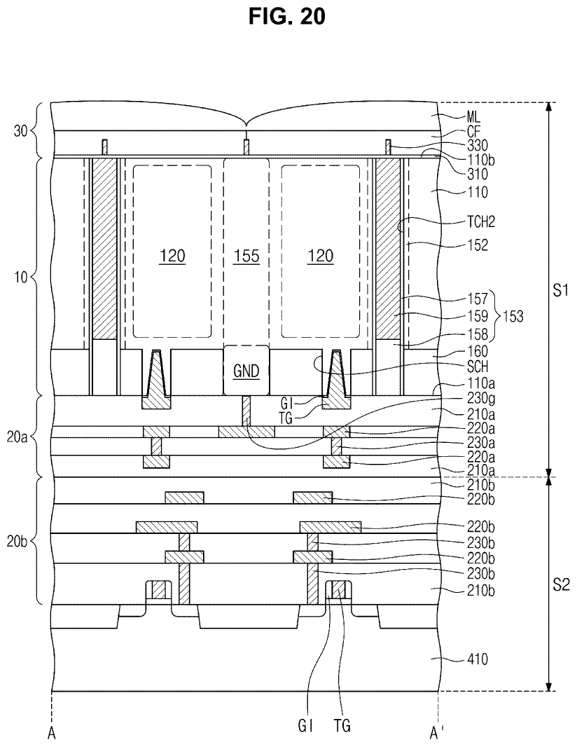

FIG. 20 is a cross-sectional view illustrating an image sensor according to an example embodiment.

Referring to FIG. 20, an image sensor according to an example embodiment may include a first structure S1 and a second structure S2. The first structure S1 may be disposed on the second structure S2. The first structure S1 may include a light transmission layer 30, a photoelectric conversion layer 10, and a first circuit interconnection layer 20a. The photoelectric conversion layer 10 may be disposed between the light transmission layer 30 and the first circuit interconnection layer 20a.

The light transmission layer 30 may include the microlenses ML, the color filters CF, the grating pattern 330, and the upper insulating layer 310 of FIGS. 13 and 14. The photoelectric conversion layer 10 may include the first deep isolation pattern 151 of FIG. 3, the photodiodes 120, the substrate 110 (hereinafter referred to as a first substrate), the second deep isolation pattern 153, the additional doped isolation region 152, a doped isolation region 155, the shared ground region GND, the shallow isolation pattern 160, the gate dielectric layer GI, the transfer gates TG of FIGS. 13 and 14, and gates and source/drain regions of the logic transistors (RX, SX, and DX of FIG. 2). The first circuit interconnection layer 20a may include the first interlayer dielectrics 210a, first interconnections 220a, ground contact plug 230g, and first contact plugs 230a. The first interlayer dielectrics 210a, the first interconnections 220a, and the first contact plugs 230a may correspond to the interlayer dielectrics 210, interconnections 220, and contact plugs 230 of FIGS. 13 and 14.

The second structure S2 may include a second substrate 410 and a second circuit interconnection layer 20b on the second substrate 410. Peripheral circuit transistors may be formed on the second substrate 410. The second circuit interconnection layer 30b may include second interlayer dielectrics 210b, second interconnections 220b, and second contact plugs 230b covering the peripheral circuit transistors. The second interconnections 220b and the second contact plugs 230b may be provided in the second interlayer dielectrics 210b to be electrically connected to the peripheral circuit transistors.

The second structure S2 may include various peripheral circuits (for example, the row decoder 2, the row driver 3, the column decoder 4, the timing generator 5, the correlated double sampler 6, the analog-to-digital converter 7, the input/output buffer 8, and the autofocusing circuit, or the like) of FIG. 1 to operate pixels in the first structure S1. For example, the second interconnections 220b, the second contact plugs 230b, and the peripheral circuit transistors may constitute the various peripheral circuits.

The second circuit interconnection layer 20b may be disposed between the first circuit interconnection layer 20a and the second substrate 410. A lowermost first interlayer dielectric 210a may be bonded to an uppermost second interlayer dielectric 210b. The first structure S1 may be electrically connected to the second structure S2 through through-electrodes in an edge region of the first structure S1. Alternatively, a first bonding pad may be disposed in a lowermost first interlayer dielectric 210a, a second bonding pad may be disposed in an uppermost second interlayer dielectric 210b, and the first bonding pad may be bonded to the second bonding pad. The first structure S1 may be electrically connected to the second structure S2 through the first and second bonding pads. The first and second bonding pads may include copper (Cu).

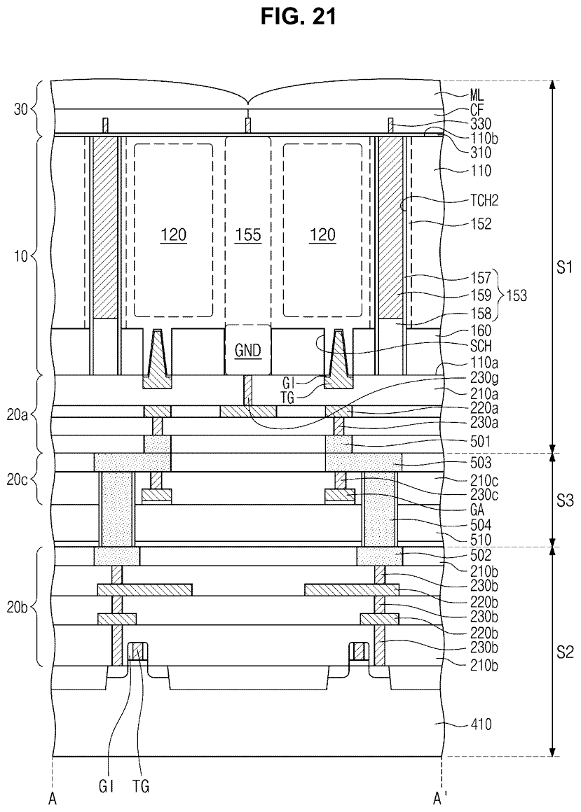

FIG. 21 is a cross-sectional view illustrating an image sensor according to an example embodiment.

Referring to FIG. 21, an image sensor according to an example embodiment may include a first structure S1, a second structure S2, and a third structure S3. The third structure S3 may be disposed between the first structure S1 and the second structure S2.

The first structure S1 may include a light transmission layer 30, a photoelectric conversion layer 10, and a first circuit interconnection layer 20a. The light transmission layer 30 may be the same as the light transmission layer 30 of FIG. 20. The photoelectric conversion layer 10 may include the first deep isolation pattern 151 of FIG. 3, the photodiodes 120, the first substrate 110, the second deep isolation pattern 153, the additional doped isolation region 152, the doped isolation region 155, the shared ground region GND, the shallow isolation pattern 160, the gate dielectric layer GI, the transfer gates TG of FIGS. 13 and 14, and gates and source/drain regions of the logic transistors (RX, SX, and DX of FIG. 2). The first circuit interconnection layer 20a may include first interlayer dielectrics 210a, first interconnections 220a, ground contact plug 230g, first contact plugs 230a, and first bonding pads 501.

The second structure S2 may include a second substrate 410 and a second circuit interconnection layer 20b on the second substrate 410. The second structure S2 may be substantially the same as the second structure S2 of FIG. 20. However, the second structure S2 may further include second bonding pads 502 provided in an uppermost second interlayer dielectric 210b.

The third structure S3 may include a third substrate 510, gates GA on the third substrate 510, and a third circuit interconnection layer 20c provided on the third substrate 510. The third substrate 510 may be a semiconductor substrate. Each of the gates GA may be disposed on the third substrate 510 with a gate dielectric layer interposed therebetween. Source/drain regions may be provided in the third substrate 510 on opposite sides adjacent to each of the gates GA.

The third circuit interconnection layer 20c may include third interlayer dielectrics 210c, third contact plugs 230c, third bonding pads 503, and fourth bonding pads 504. The third circuit interconnection layer 20c may further include third interconnections, and each of the third interconnections may be electrically connected to a corresponding gate GA, a corresponding source/drain region, a corresponding third bonding pad 503, and/or a corresponding fourth bonding pad 504.

According to an example embodiment, the first structure S1 may include some components of the pixel PXL of FIG. 2, and the third structure S3 may include other components of the pixel PXL. For example, the first structure S1 may include a photodiode PD, a transfer transistor TX, and a floating diffusion region FD of the pixel PXL, and the third structure S3 may include the logic transistors RX, SX, and DX of the pixel PXL.

In an example embodiment, the logic transistors RX, SX, and DX may be provided on the third substrate 510 below each of the pixels 131. A pixel formed in each of the pixels 131 may include all pixel transistors. Alternatively, the transistors on the third substrate may be disposed such that a pair of pixels formed in a pair of pixels 131 of a pixel group PXR share at least one of the logic transistors RX, SX, and DX.

According to an example embodiment, the first structure S1 and the third structure S3 may be bonded to each other by a copper-to-copper bonding method, and the third structure S3 and the second structure S2 may also be bonded to each other by a copper-to-copper bonding method. For example, the bonding pads 501, 502, 503, and 504 of the first, second, and third structures S1, S2, S3 may be formed of copper. The first bonding pad 501 of the first structure S1 may be bonded to the third bonding pad 503 of the third structure S3, and the second bonding pad 502 of the second structure S2 may be bonded to the fourth bonding pad 504 of the third structure S3. In an example embodiment, the fourth bonding pad 504 may be bonded to the second bonding pad 502 through the third substrate 510.

As set forth above, according to example embodiments, a single shared ground region may be formed within a pixel group, including a plurality of pixels, to reduce the number of metal interconnections.

In addition, a doped isolation region may be formed in each of a plurality of connection regions, and the shared ground region may be formed on one of the doped isolation regions. First-type Impurities may be doped in the plurality of pixels, the doped isolation regions, and the shared ground region. Accordingly, the pixels within the pixel group may be grounded through the single shared ground region. As a result, routing efficiency of metal interconnections may be improved, parasitic capacitance may be reduced, and a ghost issue of an image sensor may be suppressed.

In some example embodiments, each of the components represented by a block as illustrated in FIG. 1 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Also, at least one of these components may further include or may be implemented by a processor such as a central processing unit (CPU) that performs the respective functions, a microprocessor, or the like. Functional aspects of example embodiments may be implemented in algorithms that execute on one or more processors. Furthermore, the components, elements, modules or units represented by a block or processing steps may employ any number of related art techniques for electronics configuration, signal processing and/or control, data processing and the like.

While example embodiments have been shown and described above, it will be apparent to those skilled in the art that modifications and variations could be made without departing from the scope of the present inventive concept as defined by the appended claims.

What is claimed is:

1. An image sensor comprising:
a substrate having a first surface and a second surface opposite the first surface;
a photodiode region group comprising a plurality of photodiode regions, each of the plurality of photodiode regions comprising a photodiode;
a first deep isolation pattern provided within the substrate and surrounding the photodiode region group;
a plurality of second deep isolation patterns provided within the substrate and separating the plurality of photodiode regions from each other;
a plurality of connection regions that are connected to the plurality of photodiode regions and are provided between portions of the plurality of second deep isolation patterns that are spaced apart from each other, each of the plurality of connection regions comprising a doped isolation region; and
a shared ground region provided in one of the plurality of photodiode regions of the photodiode region group and the plurality of connection regions,
wherein the plurality of photodiode regions, the doped isolation regions, and the shared ground region are doped with impurities having a first conductivity type, and
wherein the photodiodes are doped with impurities having a second conductivity type, different from the first conductivity type.

2. The image sensor of claim 1, wherein an impurity concentration of the shared ground region is higher than an impurity concentration of the doped isolation region.

3. The image sensor of claim 2, wherein the impurity concentration of the doped isolation region is higher than an impurity concentration of the plurality of photodiode regions.

4. The image sensor of claim 1, wherein the shared ground region is provided in one of the plurality of connection regions, and is provided between the first surface of the substrate and the doped isolation region.

5. The image sensor of claim 1, wherein the shared ground region is provided in one of the plurality of pixels.

6. The image sensor of claim 1, wherein the plurality of photodiode regions are arranged in a 2N×2N matrix (where N is a positive integer) in plan view,
wherein one of the plurality of connection regions is provided at a center of the photodiode region group, and
wherein the shared ground region is provided within the connection region provided at the center of the photodiode region group, and is provided between the first surface of the substrate and the doped isolation region.

7. The image sensor of claim 1, wherein the shared ground region has a rectangular shape in plan view.

8. The image sensor of claim 1, further comprising a shallow isolation pattern filling a shallow trench recessed from the first surface of the substrate,
wherein a portion of the shallow isolation pattern is provided on the doped isolation region within at least one of the plurality of connection regions.

9. The image sensor of claim 8, wherein the plurality of photodiode regions are arranged in a 2N×2N matrix (where N is a natural number) in plan view,
wherein one of the plurality of connection regions is provided at a center of the photodiode region group,
wherein the shared ground region is provided within the connection region provided at the center of the photodiode region group, and is provided between the first surface of the substrate and the doped isolation region, and
wherein the portion of the shallow isolation pattern is provided in at least one other connection region of the plurality of connection regions.

10. The image sensor of claim 1, wherein the photodiode region group comprises four photodiode regions arranged in a 2×2 matrix in plan view,
wherein one of the plurality of connection regions is provided at a center of the four photodiode regions,
wherein a floating diffusion region is provided within the connection region provided at the center of the four photodiode regions, and is provided between the first surface of the substrate and the doped isolation region,
wherein the floating diffusion region is doped with the impurities having the second conductivity type, and
wherein the four photodiode regions share the floating diffusion region and logic transistors.

11. The image sensor of claim 10, further comprising a color filter provided on the second surface of the substrate,
wherein the color filter is on the four photodiode regions.

12. The image sensor of claim 1, wherein each of the first deep isolation pattern and each of the plurality of second deep isolation patterns comprises:
a buried pattern; and
an insulating liner between the buried pattern and the substrate, and
wherein the first deep isolation pattern and the plurality of second deep isolation patterns are connected to each other, and the buried patterns of the first deep isolation pattern and the plurality of second deep isolation patterns are connected to each other.

13. The image sensor of claim 1, further comprising a transfer gate on the first surface of the substrate.

14. The image sensor of claim 1, further comprising an additional doped isolation region provided in each of the plurality of photodiode regions,
wherein the additional doped isolation region is adjacent to a side surface of the first deep isolation pattern or a second deep isolation pattern of the plurality of second deep isolation patterns, and extends vertically along the side surface of the first deep isolation pattern or the second deep isolation pattern, and
wherein the additional doped isolation region is doped with the impurities having the first conductivity type.

15. The image sensor of claim 14, wherein the additional doped isolation region is connected to the doped isolation region.

16. An image sensor comprising:
a substrate having a first surface and a second surface opposite the first surface;
a photodiode region group comprising a plurality of photodiode regions, each of the plurality of photodiode regions comprising a photodiode;
a first deep isolation pattern provided within the substrate and surrounding the photodiode region group;
a plurality of second deep isolation patterns provided within the substrate and separating the plurality of photodiode regions from each other;
a plurality of connection regions that are connected to the plurality of photodiode regions and are provided between the plurality of second deep isolation patterns spaced apart from each other, each of the plurality of connection regions comprising a doped isolation region and an additional doped isolation region;
a shared ground region provided in one of the plurality of photodiode regions of the photodiode region group and the plurality of connection regions,
wherein the additional doped isolation region is adjacent to a side surface of the first deep isolation pattern or a second deep isolation pattern of the plurality of second deep isolation patterns, and extends vertically along the side surface of the first deep isolation pattern or the second deep isolation pattern,
wherein the doped isolation regions, the additional doped isolation region, and the shared ground region are doped with impurities having a same conductivity type, and
wherein an impurity concentration of the shared ground region is higher than an impurity concentration of the doped isolation regions and the additional doped isolation region.

17. The image sensor of claim 16, wherein the shared ground region is provided in one of the plurality of connection regions, and is provided between the first surface of the substrate and the doped isolation region.

18. The image sensor of claim 16, wherein the plurality of photodiode regions are arranged in a 2N×2N matrix (where N is a positive integer) in plan view,
wherein one of the plurality of connection regions is provided at a center of the photodiode region group, and
wherein the shared ground region is provided within the connection region provided at the center of the photodiode region group, and is provided between the first surface of the substrate and the doped isolation region.

19. The image sensor of claim 16, wherein the shared ground region is provided in one of the plurality of photodiode regions.

20. An image sensor comprising:
a substrate having a first surface and a second surface opposite the first surface;
a photodiode region group comprising a plurality of photodiode regions arranged in a 2N×2N matrix (where N is a positive integer) in plan view, each of the plurality of photodiode regions comprising a photodiode;
a first deep isolation pattern provided within the substrate and surrounding the photodiode region group;
a plurality of second deep isolation patterns provided within the substrate to separate each of the plurality of photodiode regions from each other;
a plurality of connection regions that are connected to the plurality of photodiode regions and are provided between the plurality of second deep isolation patterns spaced apart from each other, each of the plurality of connection regions comprising a doped isolation region and an additional doped isolation region;
a shallow isolation pattern filling a shallow trench recessed from the first surface of the substrate; and
a shared ground region provided in one of the plurality of connection regions,
wherein the shared ground region is provided within a connection region, among the plurality of connection regions, provided at a center of the photodiode region group, and is provided between the first surface of the substrate and the doped isolation region,
wherein a portion of the shallow isolation pattern is provided on the doped isolation region within at least one other of the plurality of connection regions,
wherein the doped isolation regions and the shared ground region are doped with impurities having a same conductivity type, and
wherein an impurity concentration of the shared ground region is higher than an impurity concentration of the doped isolation regions.
